(19) United States
(12) Patent Application Publication
(10) Pub. No.: US 2013/0157384 A1
(43) Pub. Date: Jun. 20, 2013

(54) METHOD FOR FABRICATING SEMICONDUCTOR DEVICE

(71) Applicant: Jung Woo PARK, Seoul (KR)

(72) Inventor: Jung Woo PARK, Seoul (KR)

(21) Appl. No.: 13/529,176

(22) Filed: Jun. 21, 2012

(30) Foreign Application Priority Data
Dec. 16, 2011 (KR) 10-2011-0136653

(51) Int. Cl. H01L 43/12

(52) U.S. Cl. 438/3; 257/E43.006

(57) ABSTRACT

A method for fabricating a semiconductor device includes forming a first insulation layer over a bottom layer, selectively removing a portion the first insulation layer to form a first trench that exposes the bottom layer, forming spacers on inner sidewalls of the first trench; forming a pillar-shaped second insulation layer in the first trench between the spacers, removing the spacers to form a second trench between the pillar-shaped second insulation layer and the first insulation layer, and burying a conductive layer in the second trench.

### CROSS-REFERENCE TO RELATED APPLICATIONS

The present application claims priority of Korean Patent Application No. 10-2011-0136653, filed on Dec. 16, 2011, which is incorporated herein by reference in its entirety.

### BACKGROUND

1. Field

Exemplary embodiments of the present invention relate to a method for fabricating a semiconductor device, and more particularly, to a method for fabricating a semiconductor device that is capable of improving the process reliability of a micro pattern.

2. Description of the Related Art

Most electronic devices are implemented by semiconductor devices. While technology advances and develops, semiconductor devices with features for increased performance may be useful. For example, a semiconductor memory device that is capable of storing a larger amount of data may be useful.

In a semiconductor device, an insulation layer or conductive layer is formed over a wafer, and a pattern having a desired shape is formed over the insulation layer or conductive layer. During this process, the insulation layer or conductive layer is patterned by using the pattern as an etch mask. As the process is repetitively performed, a designed circuit is implemented over the wafer. The size of patterns may be reduced to increase the integration of a semiconductor device. For example, the size of patterns has been reduced to such a level as difficult to be implemented by semiconductor fabrication equipment. Accordingly, a method for stably fabricating a pattern that cannot be implemented by semiconductor fabrication equipment may be useful.

### SUMMARY

An embodiment of the present invention is directed to a method for fabricating a semiconductor device, which is capable of increasing the process reliability of micro patterns.

In accordance with an embodiment of the present invention, a method for fabricating a semiconductor device includes: forming a first insulation layer over a bottom layer; selectively removing a portion the first insulation layer to form a first trench that exposes the bottom layer; forming spacers on inner sidewalls of the first trench; forming a pillar-shaped second insulation layer in the first trench between the spacers; removing the spacer to form a second trench between the pillar-shaped second insulation layer and the first insulation layer; and burying a conductive layer in the second trench.

In accordance with another embodiment of the present invention, a method for fabricating a semiconductor device includes:

forming a first insulation layer over a bottom layer; selectively removing a portion of the first insulation layer to form a first trench that exposes the bottom layer; forming conductive spacers on inner sidewalls of the first trench; forming a pillar-shaped second insulation layer in the first trench between the conductive spacers; and performing a planarization process on upper portions of the first insulation layer, the pillar-shaped second insulation layer, and the conductive spacers.

### BRIEF DESCRIPTION OF THE DRAWINGS

FIGS. 1A to 1G are cross-sectional views illustrating a method for fabricating a semiconductor device to explain the present invention.

FIGS. 2A to 2I are cross-sectional views illustrating a method for fabricating a semiconductor device in accordance with an embodiment of the present invention.

FIG. 3 three-dimensionally illustrates the semiconductor device fabricated by the method illustrated in FIGS. 2A to 2I.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

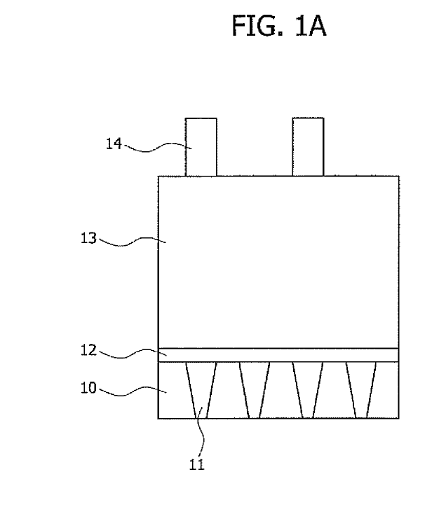

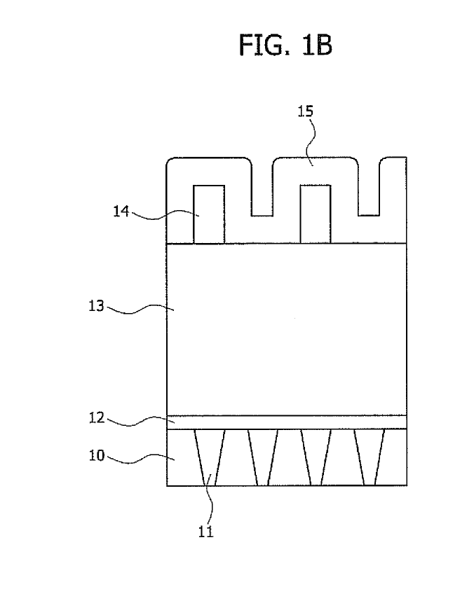

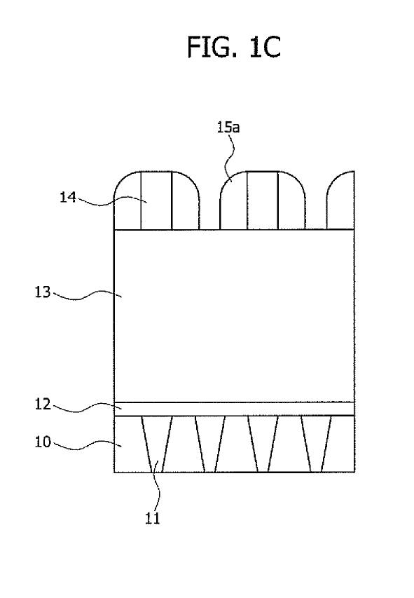

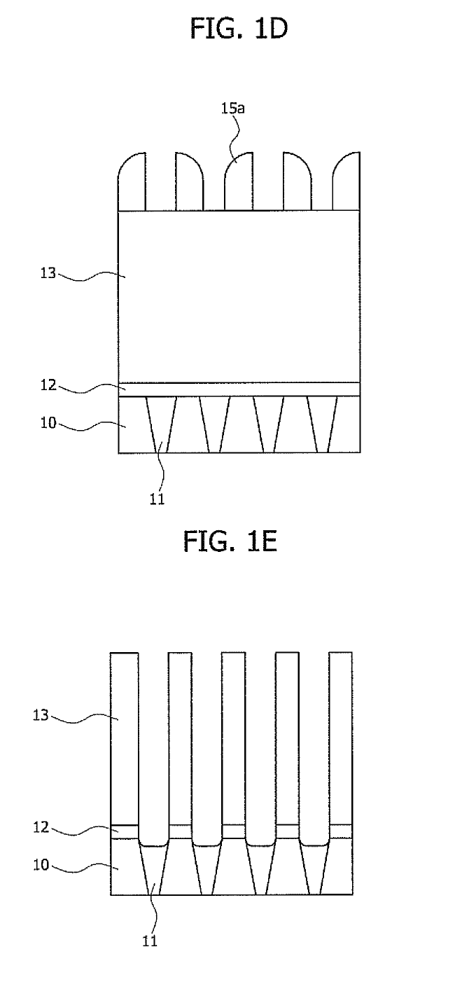

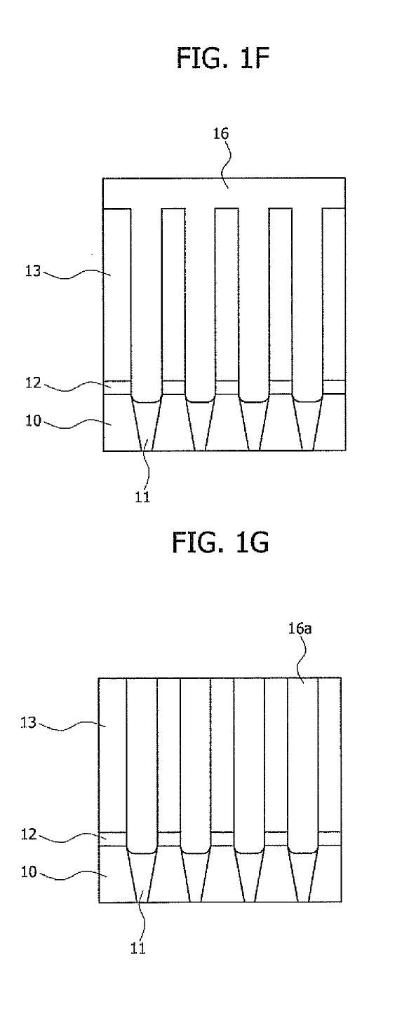

FIGS. 1A to 1G are cross-sectional views illustrating a method for fabricating a semiconductor device to explain the present invention.

Referring to FIG. 1A, an etch stop layer 12 is formed over a bottom layer 10, and a contact plug 11 is formed in the bottom layer 10. Subsequently, an insulation layer 13 is formed over the etch stop layer 12, and a photoresist pattern 14 is formed over the insulation layer 13.

The photoresist pattern 14 serves as a sacrifice layer for forming an electrode during a subsequent process. The electrode is formed in one-to-one correspondence with the contact plug 11, and the photoresist pattern is formed in two-to-one correspondence with the contact plug 11.

Referring to FIG. 1B, a spacer layer 15 is formed over the insulation layer 13 along the shape of the photoresist pattern 14.

Referring to FIG. 1C, a portion of the spacer layer 15 above the photoresist pattern 14 is removed to expose the top surface of the photoresist pattern 14, and a portion of the spacer layer 15 above the insulation layer 13 between the photoresist patterns 14 is also removed to expose the top surface of the insulation layer 13. By removing the portions of the spacer layer 15, a spacer 15a remains on the sidewalls of the photoresist pattern.

Referring to FIG. 1D, the photoresist pattern 14 is removed.

Referring to FIG. 1E, a portion of the insulation layer 13 is selectively removed by using the spacer 15a as an etch mask, thereby forming a trench that exposes the contact plug 11. A bottom electrode is to be formed in the trench.

Referring to FIG. 1F, a conductive layer 16 is buried in the trench. The conductive layer 16 may include a metal layer or a conductive polysilicon layer.

Referring to FIG. 1G, the conductive layer 16 is selectively removed to expose the top surface of the insulation layer 13, thereby forming a bottom electrode 16a. A magnetic tunneling junction (MTJ) element or capacitor (not illustrated) is formed over the bottom electrode 16a. In another type of memory cell, another material to be coupled to the bottom electrode may be formed and contacted with the bottom electrode 16a. In this example, the bottom electrode has been described as a finally-formed pattern. However, any micro patterns included in the semiconductor device may be formed as described above.

In the above-described method for fabricating a semiconductor device, the photoresist pattern 14 is formed in two-to-one correspondence with the contact plug 11, instead of the one-to-one correspondence, and the bottom electrode is formed by using the spacer. The photoresist pattern 14 is formed in a two-to-one correspondence with the contact plug 11 because the pattern size of the bottom electrode 16a is small, and forming a photoresist pattern 14 for the bottom electrode 16a may be difficult. Although the photoresist pattern 14 is formed in a desired size, the insulation layer 13 is difficult to reliably pattern using the photoresist pattern 14 as an etch mask.

Because the insulation layer 13 is difficult to pattern using the photoresist pattern 14 as an etch mask, the photoresist patterns 14 are formed at relatively large intervals, and the insulation layer 13 is patterned by using the spacers 15a formed on the left and right sidewalls of each photoresist pattern 14.

However, the critical dimension (CD) is difficult to control in the method using the spacers 15a because the CD of the photoresist patterns 14 is difficult to control. Furthermore, during the process of patterning the insulation layer 13 using the spacers 15a, a trench is difficult to stably form because the etched portion of the insulation layer 13 has a small width. Furthermore, even when the conductive layer 16 is buried in the trench formed in the insulation layer 13, the reliability of the semiconductor device is difficult to increase due to difficulties in gap-filling.

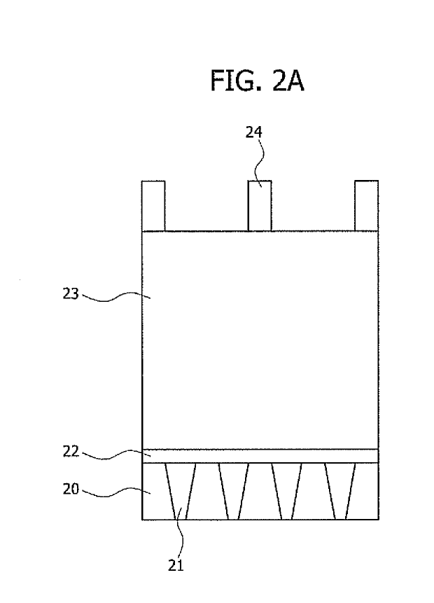

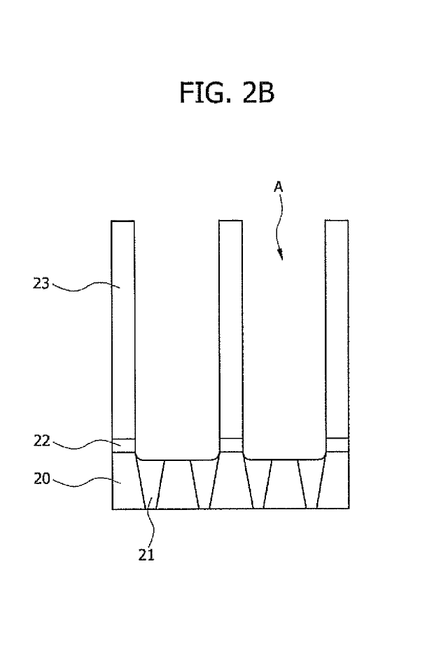

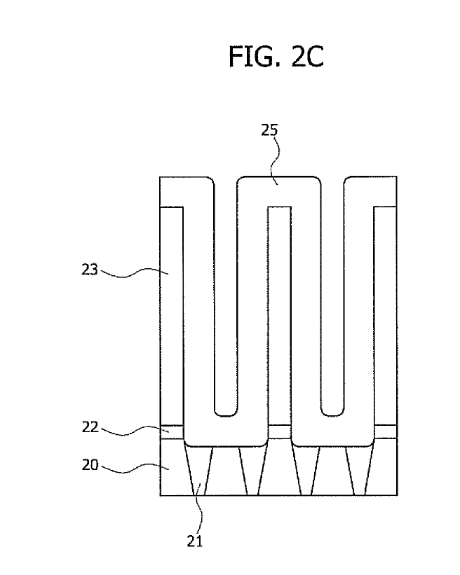

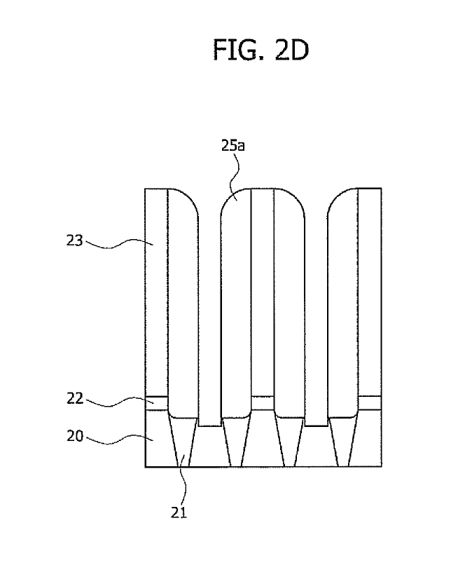

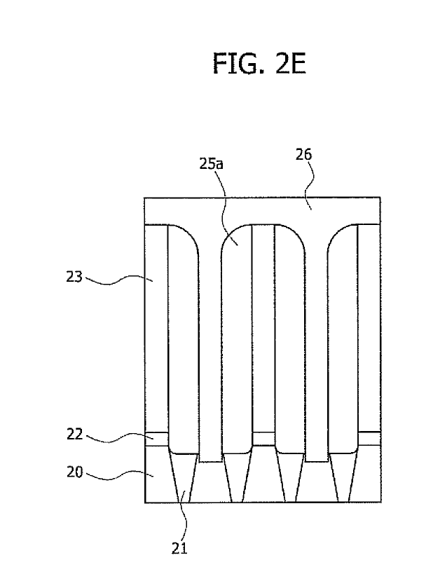

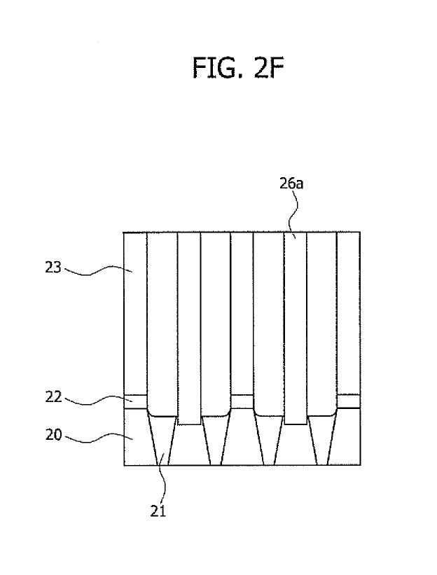

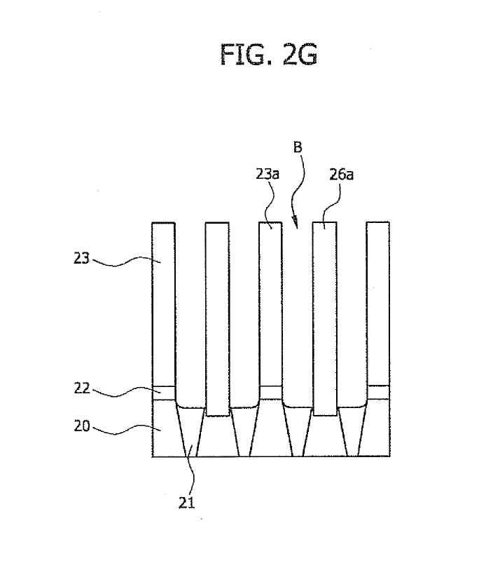

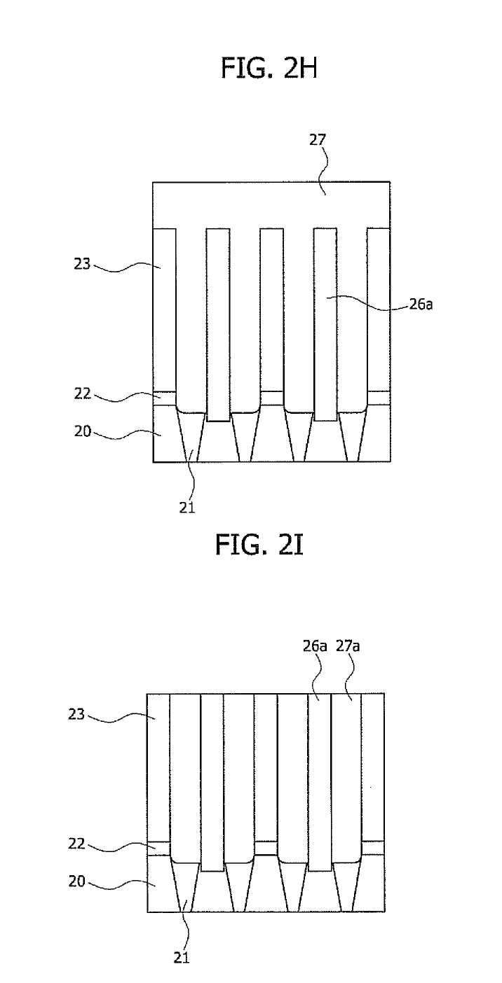

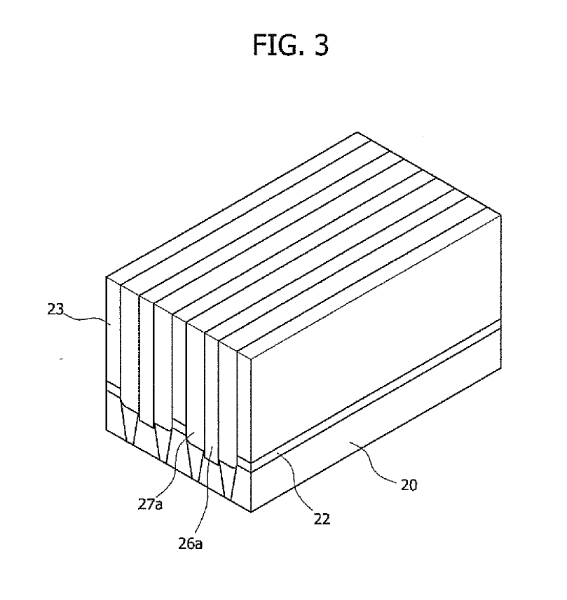

FIGS. 2A to 2I are cross-sectional views illustrating a method for fabricating a semiconductor device in accordance with an embodiment of the present invention.

Referring to FIG. 2A, an etch stop layer 22 is formed over a bottom layer 20, and a contact plug 21 is formed in the bottom layer 20. An insulation layer 23 is formed over the etch stop layer 22.

A photoresist pattern 24 is formed over the insulation layer 23.

Here, the photoresist pattern 24 is formed to expose two contact plugs 21.

Referring to FIG. 2B, a first trench A is formed by patterning the insulation layer 23 using the photoresist pattern 24 as an etch mask. During this process, the etch stop layer 22 serves to stop the etching process. After etching the insulation layer 23, the photoresist pattern 24 is removed.

Referring to FIG. 2C, a spacer layer 25 is formed along the shape of the first trench A. The spacer layer 25 is formed of a material having an etching selectivity with the insulation layer 23, and may include polysilicon, carbon, SiGe, amorphous silicon, etc.

Referring to FIG. 2D, an etching process is performed to expose the top surface of the insulation layer 23 and the top surface of the bottom layer 20 between two contact plugs 21 in the first trench A. As a result of the etching process, the spacer layer 25 remains on the inner sidewalls of the hole A, thereby forming a spacer 25a.

Referring to FIG. 2E, an insulation layer 26 is formed to fill the first trench A. For example, the insulation layer 26 may include an insulation layer having an excellent burial characteristic, such as an oxide-based layer, or an NIT, or low-k layer.

Referring to FIG. 2F, the insulation layer 26 is selectively removed to expose the top surface of the insulation layer 23. During this process, an upper portion of the spacer 25a may also be removed. Through this process, a pillar-pattern insulation layer 26a is formed.

Referring to FIG. 2G, the spacer 25a is removed. As a result, a second trench B is formed between the pillar-portion insulation layer 26a and the insulation layer 23

Referring to FIG. 2H, a bottom-electrode conductive layer 27 is filled in the second trench B. The bottom-electrode conductive layer 27 may include tungsten, titanium nitride, or conductive polysilicon.

Referring to FIG. 2I, the bottom-electrode conductive layer 27 is selectively removed to expose the top surface of the pillar-pattern insulation layer 26a and the top surface of the insulation layer 23, thereby forming a bottom electrode 27a. This process may be performed by a chemical mechanical polishing (CMP) process.

An MTJ element or capacitor is formed over the bottom electrode 27a. In another type of memory cell, another material coupled to the bottom electrode 27a may be formed and contacted with the bottom electrode 27a. In this embodiment of the present invention, the bottom electrode 27a has been described as a finally-formed pattern. However, any micro patterns included in the semiconductor device may be formed as described above.

FIG. 3 three-dimensionally illustrates the semiconductor device fabricated by the method illustrated in FIGS. 2A to 2I. The semiconductor device in accordance with the embodiment of the present invention includes the lower electrodes 27a between the insulation layer 23 and the pillar-pattern insulation layer 26a, respectively, over the bottom layer 20.

In the above-described method for fabricating a semiconductor device, when the bottom electrode 27a as a micro pattern is formed, a mask is not directly used. The spacer layer 25 is first formed, the pillar-pattern insulation layer 26 is formed in the spaces between the spacer layers 25a, and the bottom electrodes 27a are subsequently formed in the second trenches B.

Furthermore, the second trench B for forming the bottom electrode 27a as a micro pattern is formed by the process of removing the spacer layer 25a without performing a patterning process, unlike the fabrication method illustrated in FIGS. 1A to 1G.

The patterning process illustrated in FIG. 1E selectively removes the insulation layer at a small width. Therefore, the patterning process may be difficult to perform, and the size of the insulation layer 23 is limited. However, in the method for fabricating a semiconductor device in accordance with the embodiment of the present invention, the process of FIG. 1E is not necessary, and the burying process is used. Therefore, the height of the insulation layer 23 may be further increased.

When the spacer layer 25 is formed of a conductive layer, the bottom electrode 27a is formed in the process of FIG. 2F, and the processes illustrated in FIGS. 2G to 2I may be omitted. Here, the conductive layer for the spacer layer may include tungsten or titanium nitride, and the conductive layer may be formed by chemical vapor deposition or atomic layer deposition.

The size of patterns forming a semiconductor device may be 30 nm or less. Even when semiconductor fabrication equipment cannot stably fabricate micro patterns, the method for fabricating a semiconductor device in accordance with the embodiment of the present invention may be applied to reliably form micro patterns.

In accordance with the embodiment of the present invention, the method for fabricating a semiconductor device may improve the process reliability of micro patterns.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor device, comprising:
forming a first insulation layer over a bottom layer;
selectively removing a portion the first insulation layer to form a first trench that exposes the bottom layer;
forming spacers on inner sidewalls of the first trench;
forming a pillar-shaped second insulation layer in the first trench between the spacers;
removing the spacers to form a second trench between the pillar-shaped second insulation layer and the first insulation layer; and
burying a conductive layer in the second trench.

2. The method of claim 1, further comprising forming a plurality of contact holes in the bottom layer,
wherein the first trench exposes two contact holes, and the conductive layer is contacted with the exposed contact holes.

3. The method of claim 1, wherein the conductive layer comprises a metal layer.

4. The method of claim 1, further comprising forming a magnetic tunneling junction (MTJ) element over the conductive layer and using the conductive layer as a bottom electrode.

5. The method of claim 1, further comprising forming a material having capacitance over the conductive layer and using the conductive layer as a bottom electrode.

6. A method for fabricating a semiconductor device, comprising:
forming a first insulation layer over a bottom layer;
selectively removing a portion of the first insulation layer to form a first trench that exposes the bottom layer;
forming conductive spacers on inner sidewalls of the first trench;
forming a pillar-shaped second insulation layer in the first trench between the conductive spacers; and
performing a planarization process on upper portions of the first insulation layer, the pillar-shaped second insulation layer, and the conductive spacers.

7. The method of claim 6, wherein the forming of the conductive spacers comprises:
forming a spacer layer along the shape of the first trench; and
removing a portion of the spacer layer using an etching process so that the spacer layer remains on the sidewalls of the first trench.

8. The method of claim 6, further comprising forming a plurality of contact holes in the bottom layer,
wherein the first trench exposes two contact holes, and the conductive layer is contacted with the exposed contact holes.

9. The method of claim 6, wherein the conductive layer comprises a metal layer.

10. The method of claim 6, further comprising forming an MTJ element over the conductive layer and using the conductive layer as a bottom electrode.

11. The method of claim 6, further comprising forming a material having capacitance over the conductive layer and using the conductive layer as a bottom electrode.
